(19) United States
(12) Patent Application Publication
(10) Pub. No.: US 2016/0036434 A1
(43) Pub. Date: Feb. 4, 2016

(54) SEMICONDUCTOR INTEGRATED CIRCUIT DEVICE

(71) Applicant: KABUSHIKI KAISHA TOSHIBA, Tokyo (JP)

(72) Inventors: Hiroyuki HARA, Fujisawa Kanagawa (JP); Tetsuya FUJITA, Kawasaki Kanagawa (JP)

(21) Appl. No.: 14/634,865

(22) Filed: Mar. 1, 2015

(30) Foreign Application Priority Data
Aug. 4, 2014 (JP) 2014-159055

(51) Int. Cl. H03K 17/687

(52) U.S. Cl. CPC H03K 17/687

(57) ABSTRACT

A semiconductor integrated circuit device includes a power domain area on a semiconductor substrate, that includes a circuit block for executing a predetermined function, a first power source line that receives an external power source voltage, a second power source line that is connected to the circuit block, a first power switch circuit in a peripheral area of the power domain area, that connects the first power source line and the second power source line in response to a first enable signal, and a second power switch circuit in the power domain area, that connects the first power source line and the second power source line in response to a second enable signal.

### CROSS-REFERENCE TO RELATED APPLICATION

This application is based upon and claims the benefit of priority from Japanese Patent Application No. 2014-159055, filed Aug. 4, 2014, the entire contents of which are incorporated herein by reference.

### FIELD

Embodiments described herein relate generally to a semiconductor integrated circuit device including multiple power domains.

### BACKGROUND

A semiconductor integrated circuit device provided with a plurality of power domains is known in the art. Power consumption is suppressed by selectively turning off a power domain which is not needed. Although a power switch for selectively supplying an external power source voltage to a power domain is provided, the supply of an external power source voltage to a power domain is subject to IR drop in the conductive path to the power switch and in the power switch itself. Accordingly, a supply method that minimizes the IR drop is desirable. Further, a rush current has to be suppressed when supplying the external power source voltage to the power domain.

### DESCRIPTION OF THE DRAWINGS

FIG. 1 is a view schematically illustrating a first embodiment of a semiconductor integrated circuit device.

FIG. 2 is a view illustrating a positional relation of power switch circuits in the semiconductor integrated circuit device of the embodiment.

FIG. 3 is a view schematically illustrating a cross sectional structure of the semiconductor integrated circuit device of the embodiment.

FIG. 4 is a view illustrating a connection relation of the power switch circuits in the semiconductor integrated circuit device of the embodiment.

FIG. 5 is a view illustrating a relation between a voltage and an enable signal supplied to the semiconductor integrated circuit device of the embodiment.

### DETAILED DESCRIPTION

In general, embodiments provide a semiconductor integrated circuit device capable of reducing IR drop in a power supply path to a power domain and configured with protection against a rush current.

In general, according to one embodiment, a semiconductor integrated circuit device includes a power domain area on a semiconductor substrate, that includes a circuit block for executing a predetermined function, a first power source line that receives an external power source voltage, a second power source line that is connected to the circuit block, a first power switch circuit in a peripheral area of the power domain area, that connects the first power source line and the second power source line in response to a first enable signal, and a second power switch circuit in the power domain area, that connects the first power source line and the second power source line in response to a second enable signal.

Hereinafter, a semiconductor integrated circuit device according to one embodiment will be specifically described with reference to the drawings. The disclosure is not restricted to these embodiments.

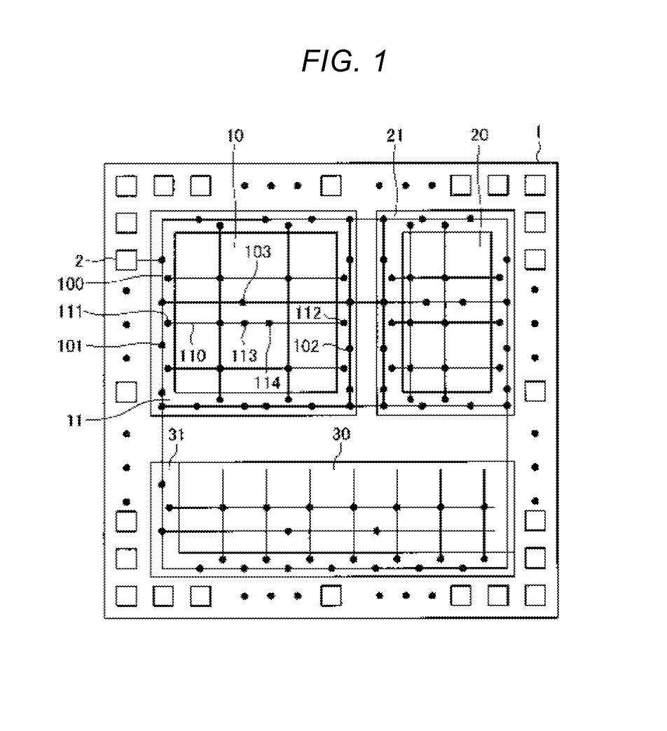

FIG. 1 is a view illustrating an embodiment of a semiconductor integrated circuit device and schematically illustrating the positional relation between respective components formed in the semiconductor integrated circuit device. A semiconductor chip 1 includes a plurality of electrode pads and an external power source voltage VDD is applied to one of the electrode pads, e.g., an electrode pad 2. The electrode pad 2 is connected to an external power supply wiring 100.

A plurality of power domain areas (10, 20, 30) are formed on the semiconductor chip 1. A power domain is an area including a circuit block for executing a predetermined function with one power source voltage applied thereto, and in FIG. 1, three power domain areas (10, 20, 30) are displayed. In the power domain areas (10, 20, 30), for example, a Central Processing Unit (CPU), a Digital Signal Processor (DSP), and a predetermined logic circuit are formed, respectively.

Peripheral areas (11, 21, 31) are provided around the respective power domain areas (10, 20, 30). For example, around the power domain areas (10, 20), the peripheral areas (11, 21) surrounding their outer peripheries are provided and around the power domain area 30, the peripheral area (31) is provided on the two sides thereof. A first power switch circuit (not illustrated) and a second power switch circuit (not illustrated) are formed in the peripheral areas (11, 21, 31). A third power switch circuit (not illustrated) is formed in the power domain area 10. Since each of the power domain areas (10, 20, 30) and each of the peripheral areas (11, 21, 31) thereof may be formed as in integrated structure, the structure of the first power domain area 10 and its peripheral area 11 will be described as an example.

An external power supply wiring 100 is connected to the first power switch circuit formed in the peripheral area 11, through an input connection node 101, and connected to the second power switch circuit formed in the peripheral area 11, through an input connection node 102.

The external power supply wiring 100 is connected to the third power switch circuit formed in the power domain area 10, through an input connection node 103. By providing the input connection node 103 for the external power supply wiring 100 and the third power switch circuit in the power domain area 10, power source wiring from the third power switch circuit to the circuit block (not illustrated) formed in the power domain area 10 may be shortened, hence to reduce the IR drop. The structure including the respective power switch circuits will be described later.

Output from the first power switch circuit formed in the peripheral area 11 is supplied to an internal power supply wiring 110 through an output connection node 111. Specifically, when the first power switch circuit is in the ON state, an external power source voltage VDD is supplied to the internal power supply wiring 110 through the first power switch circuit. Similarly, when the second power switch circuit is in the ON state, the output from the second power switch circuit is supplied to the internal power supply wiring 110 through an output connection node 112. The internal power supply wiring 110 is formed in a multilayer wiring area (not illustrated) in the power domain area 10.

The internal power supply wiring 110 is connected to a circuit block (not illustrated) formed in the power domain area 10, through internal wiring connection nodes (113, 114). By turning off the first power switch circuit and the second power switch circuit, a connection between the external power supply wiring 100 and the internal power supply wiring 110 is cut off. This may interrupt a supply of the external power source voltage VDD to the power domain area 10 through the internal power supply wiring 110. For example, when a supply of a clock signal to the circuit block formed in the power domain area 10 is interrupted and the circuit block is not operated, by interrupting the supply of the external power source voltage VDD, a leak current generated in the power domain area 10 may be reduced. According to this, the power consumption may be suppressed. The description of the power domain area 10 provided above applies similarly to the other power domain areas (20, 30). The structure including the circuit block will be described later.

According to the embodiment, the external power source voltage VDD is supplied to the circuit blocks in the power domain areas (10, 20, 30) in parallel through the first and the second power switch circuits formed in the peripheral areas (11, 21, 31) of the power domain areas (10, 20, 30) and the third power switch circuit formed in the power domain areas (10, 20, 30). For example, the first power switch circuit and the second power switch circuit provides countermeasures against a rush current, the external power source voltage VDD may be supplied to the internal power supply wiring 110. Further, by providing the third power switch circuit in the power domain areas (10, 20, 30), the external power source voltage VDD may be supplied to the circuit block in the power domain areas (10, 20, 30) with the IR drop reduced.

For example, the entire capacitance in the power domain area 10 may be estimated based on the number of gates in the circuit block formed in the power domain area 10. Based on the estimation value of the capacitance, the countermeasures against the rush current are provided by the first and the second power switch circuits formed in the peripheral area 11 of the power domain area 10; therefore, simulation of the rush current may be performed at the initial stage of design. The power switch circuits to supply the external power source voltage VDD to the power domain area 10 are respectively provided in the peripheral area 11 of the power domain area 10 and in the power domain area 10, and the power switch circuits provided in the peripheral area 11 protect against the rush current; as the result, there may be provided a semiconductor integrated circuit device capable of simplifying the design and supplying the external power source voltage VDD to a circuit block in the power domain area 10, with the IR drop reduced by having the power switch circuit provided in the power domain area 10.

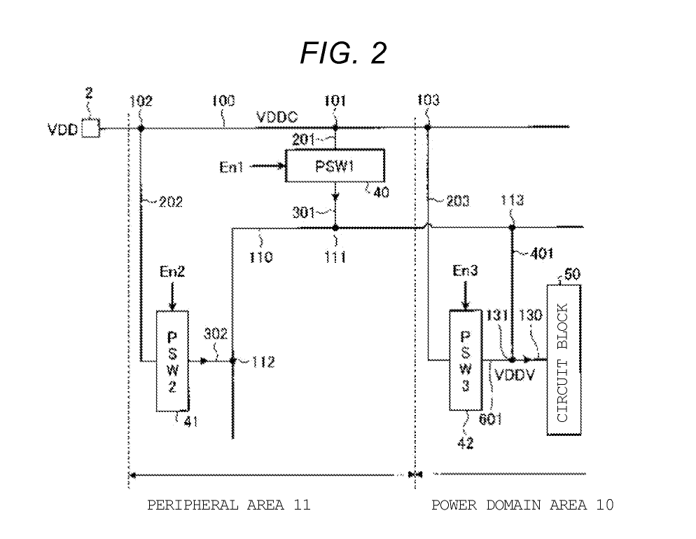

FIG. 2 is a view schematically illustrating a positional relation between the respective power switch circuits in the semiconductor integrated circuit device according to the embodiment. The same reference numbers are attached to the same components previously described. Since the respective power domain areas may be formed to have the same structure, the power domain area 10 will be described as representative.

The external power supply wiring 100 is connected to the electrode pad 2 where the external power source voltage VDD is applied. The voltage of the external power supply wiring 100 is indicated by VDDC. The external power supply wiring 100 is connected to a first power switch circuit 40 formed in the peripheral area 11 through a wiring 201, through the input connection node 101. A first enable signal En1 is supplied to the first power switch circuit 40. In response to the first enable signal En1, the first power switch circuit 40 is turned on, and then, the external power supply wiring 100 is connected to the internal power supply wiring 110 through the connection node 111 and the wiring 301.

The external power supply wiring 100 is connected to a second power switch circuit 41 formed in the peripheral area 11 through a wiring 202, through the input connection node 102. A second enable signal En2 is supplied to the second power switch circuit 41. In response to the second enable signal En2, the second power switch circuit 41 is turned on and the external power supply wiring 100 is connected to the internal power supply wiring 110 through a connection node 112 and a wiring 302. Specifically, a route passing through the second power switch circuit 41 is formed between the external power supply wiring 100 and the internal power supply wiring 110.

For example, the second enable signal En2 is supplied at a timing delayed from the first enable signal En1 by a predetermined time. The timing of turning on the first power switch circuit 40 and the second power switch circuit 41 is adjusted, to moderate the rise of the voltage applied to the internal power supply wiring 110. By moderating the rise of the voltage, the rush current may be suppressed. The internal power supply wiring 110 is connected to the lower layer wiring 130, through an internal wiring connection node 113 and the lower layer wiring 130 supplies the operation voltage VDDV to the circuit block 50 in the power domain area 10.

The external power supply wiring 100 is connected to a third power switch circuit 42 formed in the power domain area 10 through a wiring 203, through the input connection node 103. A third enable signal En3 is supplied to the third power switch circuit 42. In response to the third enable signal En3, the third power switch circuit 42 is turned on, to connect the external power supply wiring 100 to the lower layer wiring 130. For example, the third enable signal En3 is supplied at a timing delayed from the second enable signal En2 by a predetermined time.

The output of the third power switch circuit 42 is connected to the lower layer wiring 130 through a wiring 601 and a connection node 131. The third power switch circuit 42 is connected to the external power supply wiring 100 through the input connection node 103. Therefore, by turning on the third power switch circuit 42, the external power supply wiring 100 is connected to the lower layer wiring 130 through the third power switch circuit 42. By supplying the voltage VDDC of the external power supply wiring 100 to the lower layer wiring 130 through the third power switch circuit 42, the voltage of the lower layer wiring 130, specifically the operation voltage VDDV supplied to the circuit block 50 may be raised. Since the voltage of the lower layer wiring 130 is increased through the countermeasures against the rush current, by the first power switch circuit 40 and the second power switch circuit 41, the countermeasures against the rush current do not have to be provided by the third power switch circuit 42 and the circuit structure may be simplified.

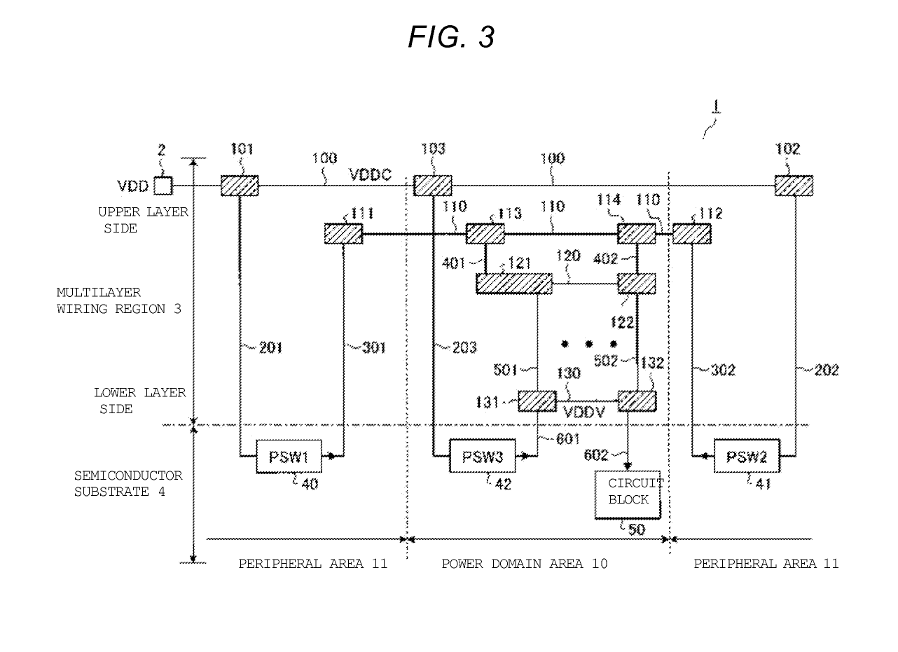

FIG. 3 is a view schematically illustrating the cross sectional structure of the semiconductor integrated circuit device according to the embodiment. The same reference numbers are attached to the same components previously described. Since the respective power domain areas (10, 20, 30) may be formed to have the same structure, the power domain area 10 will be described as representative. The cross sectional structure as illustrated in FIG. 3 is formed on the semiconductor chip 1. The external power source voltage VDD is supplied to the electrode pad 2 formed on the semiconductor chip 1. The electrode pad 2 is connected to the external power supply wiring 100 formed on the side of the upper layer of the multilayer wiring region 3.

The external power supply wiring 100 is connected to the first power switch circuit 40 formed in the peripheral area 11 through the wiring 201 connected to the input connection node 101. The wiring 201 is formed by a combination of, for example, vias formed in a multilayer wiring area 3 and a multilayer wiring (not illustrated). A via is formed by etching, for example, an interlayer insulating film (not illustrated) formed in the multilayer wiring region 3 to open the via hole (not illustrated) and embedding a metal material in the via hole. The wiring on the side of the upper layer, the wiring on the side of the lower layer, or the wiring for connecting circuit elements formed on a semiconductor substrate 4 may be formed in the same way. For example, the connection structure between the wirings through the vias is shown as a connection node.

The output of the first power switch circuit 40 is connected to the internal power supply wiring 110 through the output connection node 111 and the wiring 301.

The external power supply wiring 100 is connected to the second power switch circuit 41 formed in the peripheral area 11 through the wiring 202 connected to the input connection node 102. The output of the second power switch circuit 41 is supplied to the internal power supply wiring 110 through the internal wiring connection node 112 and the wiring 302.

The internal power supply wiring 110 is connected to an internal wiring 120 through a wiring 401 and a wiring 402. The internal wiring 120 is a wiring for supplying a voltage of the internal power supply wiring 110 to the wiring layer on the side of the lower layer. The internal wiring 120 is connected to the lower layer wiring 130 in a connection node 131 and a connection node 132 thereof through a wiring 501 and a wiring 502 respectively connected to a connection node 121 and a connection node 122. In FIG. 2, for the sake of convenience, the description has been made in the case where a connection between the internal power supply wiring 110 and the lower layer wiring 130 is established by the wiring 401.

The external power supply wiring 100 is connected to the third power switch circuit 42 formed in the power domain 10 through the wiring 203 connected to the input connection node 103. The output of the third power switch circuit 42 is supplied to the lower layer wiring 130 through the connection node 131 and the wiring 601. The lower layer wiring 130 is connected to a wiring 602 through the connection node 132, to supply the operation voltage VDDV to the circuit block 50. The lower layer wiring 130 is formed, for example, by the wiring of the undermost layer formed on the semiconductor substrate 4. The wiring 602 is formed, for example, by the connection of the lower layer wiring 130 and the circuit block 50 through an opening (not illustrated) formed on the semiconductor substrate 4.

According to the embodiment, the operation voltage VDDV is supplied to the circuit block 50 in the power domain area 10 through a route that passes through the first power switch circuit 40 and the second power switch circuit 41 formed in the peripheral area 11 of the power domain area 10 and a route that passes through the third power switch circuit 42 formed in the power domain area 10.

The third power switch circuit 42 is formed in the power domain area 10 and the output voltage thereof is supplied to the circuit block 50, passing through the lower layer wiring 130 provided on the side of the lower layer of the multilayer wiring region 3. For example, the output voltage of the third power switch circuit 42 is connected to the lower layer wiring 130 by a metal material filled in the opening (not illustrated) of the insulating film (not illustrated) provided on the semiconductor substrate 4. Accordingly, by using the wiring layer on the side of the lower layer of the multilayer wiring region 3, the wiring length ranging from the third power switch circuit 42 to the circuit block 50 may be reduced. By shortening the wiring length, the IR drop is reduced; therefore, by passing through the third power switch circuit 42, the external power source voltage VDD may be supplied to the circuit block 50 of the power domain area 10 through the path with the IR drop reduced. By reducing the IR drop, the operation voltage VDDV supplied to the circuit block 50 may be raised, hence to speed up the operation of the circuit block 50. Since the operation voltage VDDV may be raised, for example, when the operation speed of the circuit block 50 is maintained at a constant speed, the size of the circuit element (not illustrated) forming the circuit block 50 may be reduced, hence to reduce the chip area.

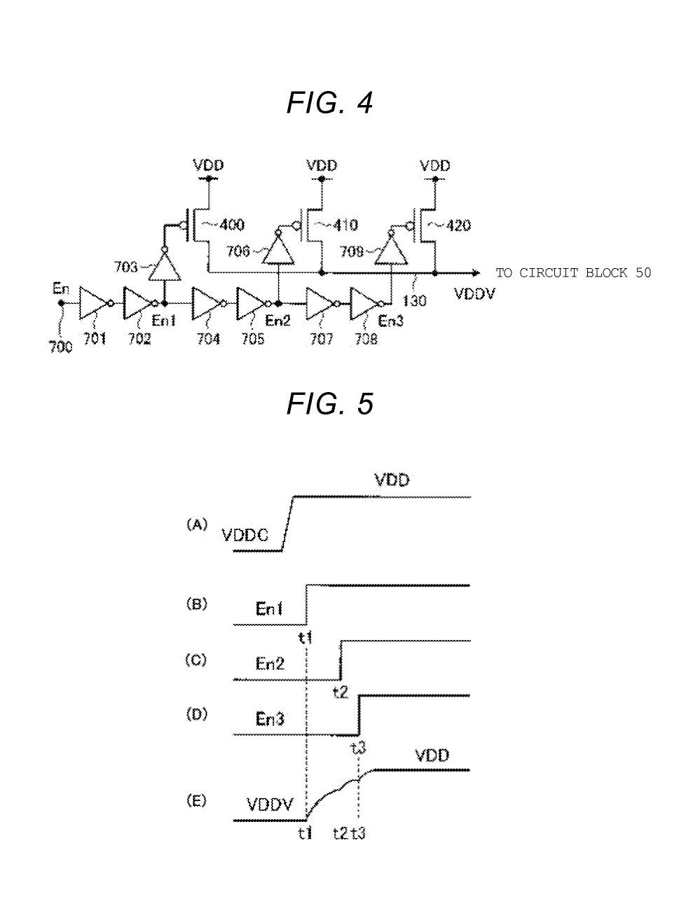

FIG. 4 is a view illustrating a connection relation of the power switch circuits in the semiconductor integrated circuit device according to the embodiment. The same reference numbers are attached to the same components previously described. Since the respective power domain areas (10, 20, 30) may be formed to have the same structure, the power domain area 10 will be described as representative. The respective power switch circuits (40 to 42) are indicated by respective PMOS transistors (400, 410, 420). The first power switch transistor 400 corresponds to the first power switch circuit 40, the second power switch transistor 410 corresponds to the second power switch circuit 41, and the third power switch transistor 420 corresponds to the third power switch circuit 42.

An enable signal En is supplied to a control terminal 700. The enable signal En is delayed by inverters (701, 702) and becomes a first enable signal En1. The first enable signal En1 is inverted by an inverter 703 and supplied to the first power switch transistor 400. The first enable signal En1 is further delayed by inverters (704, 705) and becomes a second enable signal En2. The second enable signal En2 is inverted by an inverter 706 and supplied to the second power switch transistor 410. The second enable signal En2 is delayed by inverters (707, 708) and becomes a third enable signal En3. The third enable signal En3 is inverted by an inverter 709 and supplied to the third power switch transistor 420. In other words, the first enable signal En1 is supplied to the first power switch transistor 400 first, then the second enable signal En2 is supplied to the second power switch transistor 410, and then the third enable signal En3 is supplied to the third power switch transistor 420.

By changing the number of steps of the inverters (704, 705, 707, 708) provided between the power switch transistors (400, 410, 420), the timing of generating the respective enable signals (En1 to En3) may be adjusted. In some embodiments, the enable signals (En1 to En3) may be separately generated. The external power source voltage VDD is applied to the source electrodes of the power switch transistors (400, 410, 420) forming the respective power switch circuits and the drain electrodes are connected to the circuit block 50 through the lower layer wiring 130.

### Fifth Embodiment

FIG. 5 is a view illustrating a relation between the voltage and the enable signal supplied to the semiconductor integrated circuit device according to the embodiment. The relation between the operation and the voltage of the respective power switch circuits in FIG. 4 will be described using FIG. 5. FIG. 5(A) indicates the voltage VDDC of the external power supply wiring 100 connected to the electrode pad 2. The external power source voltage VDD is applied to the electrode pad 2, and the voltage VDDC of the external power supply wiring 100 is raised to VDD. At the timing t1, the first enable signal En1 becomes H level, as shown in FIG. 5(B), and the inverted signal is supplied to the gate electrode of the first power switch transistor 400 through the inverter 703. According to this, the first power switch transistor 400 is turned on and the operation voltage VDDV of the lower layer wiring 130 is raised (FIG. 5(E)).

At the timing t2, the second enable signal En2 becomes H level, as shown in FIG. 5(C), and the inverted signal is supplied to the gate electrode of the second power switch transistor 410 through the inverter 706. According to this, the second power switch transistor 410 is turned on and the operation voltage VDDV of the lower layer wiring 130 is further raised ((FIG. 5 (E)). At the timing t3 when the operation voltage VDDV of the lower layer wiring 130 is raised to a degree, the third enable signal En3 becomes H level, as shown in FIG. 5(D), and the inverted signal is supplied to the gate electrode of the third power switch transistor 420 through the inverter 709. According to this, the third power switch transistor 420 is turned on and the operation voltage VDDV of the lower layer wiring 130 is further raised (FIG. 5(E)).

As mentioned above, the rising of the operation voltage VDDV supplied to the circuit block 50 is moderated by the first power switch transistor 400, the second power switch transistor 410, and the third power switch transistor 420, and therefore, a co-called rush current is suppressed.

In the stage of turning on the third power switch transistor 420, since the first power switch transistor 400 and the second power switch transistor 410 are turned on, the operation voltage VDDV of the lower layer wiring 130 connected to the circuit block 50 is raised. As a result, the voltage between source and drain of the third power switch transistor 420 becomes smaller and the driving ability is deteriorated; however, the third power switch transistor 420 is formed in the power domain area 10, and the wiring length to the circuit block 50 is short, hence to reduce the IR drop. Then, by providing a path passing through the third power switch transistor 420, the external power source voltage VDD may be supplied to the lower layer wiring 130 through the path with a reduced IR drop, hence to raise the operation voltage VDDV supplied to the circuit block 50.

Although each of the power switch circuits is represented by one MOS transistor, a plurality of MOS transistors (not illustrated) connected in parallel may form each power switch circuit and the enable signal may be supplied to the respective gate electrodes of the respective MOS transistors. Further, the enable signals may be supplied to the respective gate electrodes of the plural MOS transistors that make up the first power switch circuit 40 at respective delayed timings and the timings of turning on the respective MOS transistors may be adjusted in order to provide countermeasures against the rush current. In this case, for example, the second power switch circuit 41 provided in the peripheral area 11 does not have to be provided separately. This is because the first power switch circuit 40 may provide the protection against the rush current.

Even when the third power switch circuit 42 is formed by a plurality of MOS transistors, the enable signal is supplied to the gate electrodes of the respective MOS transistors at the same time and the transistors may be turned on at the same time. Since the countermeasures against the rush current are provided by the first power switch circuit 40 and the second power switch circuit 41 formed in the peripheral area 11 of the power domain area 10, the third power switch circuit 42 may be designed to supply the external power source voltage VDD without delay to the lower layer wiring 130.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit device comprising:
a semiconductor substrate;
a power domain area on the semiconductor substrate, that includes a circuit block for executing a predetermined function;
a first power source line that receives an external power source voltage;
a second power source line that is connected to the circuit block;
a first power switch circuit in a peripheral area of the power domain area, that connects the first power source line and the second power source line in response to a first enable signal; and
a second power switch circuit in the power domain area, that connects the first power source line and the second power source line in response to a second enable signal.

2. The device according to claim 1, further comprising:
a third power switch circuit in the power domain area that connects the first power source line and the second power source line in response to a third enable signal.

3. The device according to claim 2, wherein
the first enable signal is supplied prior to the second enable signal.

4. The device according to claim 3, wherein
the third enable signal supplied to the third power switch circuit is supplied after the second enable signal is supplied.

5. The device according to claim 4, wherein the enable signals are generated by passing a signal through a series of inverters.

6. The device according to claim 2, wherein
a power supply path from the external power source voltage to the circuit block is shorter through the second power switch circuit than through either the first power switch circuit or the third power switch circuit.

7. The device according to claim 2, wherein
an IR drop in a power supply path from the external power source voltage to the circuit block is less when the power supply path passes through the third power switch circuit than when the power supply path passes through either the first power switch circuit or the second power switch circuit.

8. The device according to claim 2, wherein
the first, second, and third power switch circuits are each a MOS transistor and the enable signals are each supplied to a gate of the respective MOS transistor.

9. The device according to claim 8, wherein
each of the MOS transistor comprises a single MOS transistor.

10. The device according to claim 8, wherein
each of the MOS transistor comprises a series of MOS transistors.

11. A method of supplying power from an external power source voltage to a circuit block in a power domain area of a semiconductor integrated circuit device, said method comprising:
supplying the external power source voltage through a first power source line;
in response to a first enable signal, turning on a first power switch circuit in a peripheral area of the power domain area to connect the first power source line and a second power source line that is connected to the circuit block; and
in response to a second enable signal, turning on a second power switch circuit in the power domain area to connect the first power source line and the second power source line.

12. The method according to claim 11, further comprising:
in response to a third enable signal, turning on a third power switch circuit in the power domain area to connect the first power source line and the second power source line.

13. The method according to claim 12, wherein
the first enable signal is supplied prior to the second enable signal.

14. The method according to claim 13, wherein
the third enable signal supplied to the third power switch circuit is supplied after the second enable signal is supplied.

15. The method according to claim 14, wherein the enable signals are generated by passing a signal through a series of inverters.

16. The method according to claim 12, wherein
a power supply path from the external power source voltage to the circuit block is shorter through the second power switch circuit than through either the first power switch circuit or the third power switch circuit.

17. The method according to claim 12, wherein
an IR drop in a power supply path from the external power source voltage to the circuit block is less when the power supply path passes through the third power switch circuit than when the power supply path passes through either the first power switch circuit or the second power switch circuit.

18. The method according to claim 12, wherein
the first, second, and third power switch circuits are each a MOS transistor and the enable signals are each supplied to a gate of the respective MOS transistor.

19. The method according to claim 18, wherein
each of the MOS transistor comprises a single MOS transistor.

20. The method according to claim 18, wherein
each of the MOS transistor comprises a series of MOS transistors.
